(19) United States
(12) Patent Application Publication
(10) Pub. No.: US 2026/0243806 A1
(43) Pub. Date: Aug. 20, 2026

(54) MULTI SENSOR AND MANUFACTURING METHOD THEREOF

(71) Applicant: KOREA ELECTRONICS TECHNOLOGY INSTITUTE, Seongnam-si (KR)

(72) Inventors: Hyung Man LEE, Gwangju-si (KR); Sunha LEE, Seongnam-si (KR)

(21) Appl. No.: 19/645,940

(22) Filed: Apr. 13, 2026

(30) Foreign Application Priority Data
Feb. 17, 2025 (KR) 10-2025-0020204
Apr. 11, 2025 (KR) 10-2025-0047469

(51) Int. Cl. G01R 17/10; G01R 15/20

(52) U.S. Cl. CPC G01R 17/10; G01R 15/20

(57) ABSTRACT

Proposed is a multi-sensor including a current detection unit detecting current flowing through an object to be measured. The current detection unit may include a plurality of arc-shaped arc portions combined to form a ring. The arc portion may include a plurality of curved portions disposed at different radii r(i) in a radial direction from a center of the ring and having a predetermined ring width w(i). The arc portion may also include a straight portion connecting the curved portions adjacent to each other. At least one of the plurality of curved portions may connect adjacent arc portions. The curved portion may be provided such that the ring width is proportional to the radius.

### CROSS-REFERENCE TO RELATED APPLICATIONS

This application claims priority under 35 U.S.C. § 119 to Korean Patent Application No. 10-2025-0020204, filed on Feb. 17^{th} 2025 and Korean Patent Application No. 10-2025-0047469, filed on Apr. 11, 2025 in the Korean Intellectual Property Office, the disclosure of each of which is incorporated herein by reference in its entirety.

### BACKGROUND

### Technical Field

The following disclosure relates to a multi-sensor and a manufacturing method thereof, and more particularly, to a multi-sensor capable of detecting current and temperature and a manufacturing method thereof.

### Description of Related Technology

In current and temperature detection technologies, it has been common to include current and temperature detection circuits in electronic products to detect overcurrent, short circuits, temperature rises, etc. In particular, technologies, such as vertical hall sensors (VHS) or current transformers (CT). have been primarily used for current detection. While these technologies are effective for measuring current, they have various limitations in terms of miniaturization and manufacturing costs.

### SUMMARY

One aspect is a multi-sensor having excellent linearity, reproducibility, accuracy, and sensitivity, and a manufacturing method thereof.

Another aspect is a multi-sensor capable of reducing hysteresis and a manufacturing method thereof.

The aspects of the present invention are not limited to those mentioned herein, and other aspects not mentioned will be clearly understood by those skilled in the art from the description below.

Another aspect is a multi-sensor including a current detection unit detecting current flowing through an object to be measured, wherein the current detection unit includes: a plurality of arc-shaped arc portions combined to form a ring, wherein the arc portion includes: a plurality of curved portions disposed at different radii r(i) in a radial direction from a center of the ring and having a predetermined ring width w(i); and a straight portion connecting the curved portions adjacent to each other, wherein at least one of the plurality of curved portions connects adjacent arc portions, and the curved portion is provided such that the ring width is proportional to the radius.

In an embodiment, r(i)/w(i) may be provided as a fixed constant value.

In an embodiment, resistance of the current detection unit may be calculated using the following formula.

$$R = ρ \frac{l}{A} = ρ \frac{2 π r ( i )}{t \cdot w ( i )}$$

(t: thickness of a cross-section of the curved portion, A: area of the cross-section of the curved portion, p: resistivity of the current detection unit, l: length of a path through which current flows in the current detection unit)

In an embodiment, a first arc portion, a second arc portion, a third arc portion, and a fourth arc portion of the arc portion may be sequentially and evenly disposed in a circumferential direction of the ring.

In an embodiment, the first arc portion and the second arc portion may be connected by the curved portion located at an outermost edge, the second arc portion and the third arc portion may be connected by the curved portion located at an innermost edge, the third arc portion and the fourth arc portion may be connected by the curved portion located at the outermost edge, and the fourth arc portion and the first arc portion may be connected by the curved portion located at the innermost edge.

In an embodiment, a straight portion located on one side of the arc portion and a straight portion located on the other side of the arc portion with respect to a radial direction of the ring may alternately connect adjacent curved portions.

In an embodiment, the curved portion may include a first curved portion, a second curved portion, a third curved portion, a fourth curved portion, and a fifth curved portion that may be sequentially provided, wherein the first curved portion and the second curved portion may be connected by the straight portion on one side of the arc portion, the second curved portion and the third curved portion may be connected by the straight portion on the other side of the arc portion, the third curved portion and the fourth curved portion may be connected by the straight portion on the one side, and the fourth curved portion and the fifth curved portion may be connected by the straight portion on the other side.

In an embodiment, the curved portion may be disposed in a zigzag pattern.

In an embodiment, the multi-sensor may further include: a connecting portion connecting the current detection unit to an external circuit, wherein the connecting portion extends outward in the radial direction of the ring from the curved portion connecting the adjacent arc portions, and a contact portion for electrically connecting the external circuit to the current detection unit is provided at one end.

In an embodiment, the current detection unit may constitute a Wheatstone bridge.

In an embodiment, the current detection unit may be provided as a planar hall resistor (PHR) IC element or a planar magnetic resistor (PMR) IC element.

In an embodiment, the multi-sensor may further include: a substrate including the current detection unit formed on one surface; and a temperature detection unit formed on the substrate to detect temperature of the object to be measured.

Another aspect is a method of manufacturing a multi-sensor that includes forming a thin film pattern for measuring current through magnetic field detection on a substrate, wherein the thin film pattern includes a plurality of arc-shaped arc portions combined to form a ring, and the arc portion includes: a plurality of curved portions disposed at different radii r(i) in a radial direction from a center of the ring and having a predetermined ring width w(i); and a straight portion connecting the curved portions adjacent to each other, wherein at least one of the plurality of curved portions connects adjacent arc portions, and the curved portion may be provided such that the ring width may be proportional to the radius.

In an embodiment, r(i)/w(i) may be provided as a fixed constant value.

In an embodiment, resistance of the thin film pattern may be calculated using the following formula.

$$R = ρ \frac{l}{A} = ρ \frac{2 π r ( i )}{t \cdot w ( i )}$$

(t: thickness of a cross-section of the curved portion, A: area of the cross-section of the curved portion, p: resistivity of the current detection unit, l: length of a path through which current flows in the current detection unit)

In an embodiment, the thin film pattern may constitute a Wheatstone bridge.

Other features and aspects will be apparent from the following detailed description, the drawings, and the claims.

### BRIEF DESCRIPTION OF THE DRAWINGS

FIG. 1 is a block diagram illustrating a configuration of a multi-sensor according to an exemplary embodiment of the present invention.

FIG. 2 is a schematic diagram illustrating a multi-sensor according to an exemplary embodiment of the present invention.

FIGS. 3 and 4 show an arc portion of FIG. 2.

FIG. 5 is a graph illustrating performance of a current detection unit according to an exemplary embodiment of the present invention.

FIG. 6 is a graph illustrating sensitivity of a current detection unit according to an exemplary embodiment of the present invention.

FIGS. 7 and 8 are block diagrams illustrating a configuration of a multi-sensor system according to another exemplary embodiment of the present invention, respectively.

FIG. 9 is a schematic diagram illustrating a method of manufacturing a multi-sensor according to another exemplary embodiment of the present invention.

### DETAILED DESCRIPTION

The VHS is a method that detects a magnetic field in a vertical direction. To detect current, the VHS has to simultaneously detect magnetic fields in both horizontal and vertical directions. Consequently, a problem may arise in which the magnetic fields in the horizontal and vertical directions intersect each other.

Such a problem imposes limitations on miniaturization and ease of processing and causes issues, such as complex design and manufacturing and increased manufacturing costs.

The CT method has been widely used for current detection, but it has the disadvantage of being difficult to miniaturize. In addition, there are issues, such as high manufacturing costs, complex arrangement, and potential degradation of sensor precision due to problems like magnetic field leakage. In addition, applying this method to small electronic devices tends to increase production costs due to limitations in physical space.

Moreover, to simultaneously measure both current and temperature, separate sensors have to be used or different sensor technologies have to be applied, resulting in complex circuit configurations and high costs. Consequently, there has been a need for additional technological development to achieve both miniaturization and cost reduction.

Furthermore, due to hysteresis and non-linearity issues occurring in conventional magnetic field sensing technologies, there have been problems in which sensor accuracy and sensor sensitivity are reduced.

Hereinafter, exemplary embodiments of the present invention will be described in detail with reference to the accompanying drawings such that those skilled in the art may easily put the invention into practice. The invention may be embodied in various forms and is not limited to the exemplary embodiments which are described below. For the purpose of clear description of the invention, parts which are not described are omitted and like parts in the specification are referenced by like reference numerals.

In the entire specification, when it is mentioned that an element is “connected” to another element, this mention includes a case in which both elements are “directly connected to each other” and a case in which both elements are “indirectly connected to each other” with still another element interposed therebetween.

In the entire specification, when it is mentioned that an element is located “on” another element, this mention includes a case in which an element comes in contact with another element and a case in which still another element is present between both elements.

In the entire specification, when it is mentioned that an element “includes” another element, this means that the element may further include still another element without excluding still another element unless oppositely described. Terms, “about”, “substantially”, and the like indicating degrees, which are used in the entire specification when manufacturing errors and material-allowable errors specific to the mentioned meaning are given, are used to prevent an unconscientious infringer from improperly using the disclosed details. Terms, such as “step of doing” or “step of” indicating degrees, which are used in the entire specification do not mean “step for”.

Hereinafter, exemplary embodiments of the present invention will be described in detail with reference to the accompanying drawings and the contents described below. However, the present invention is not limited to the exemplary embodiments described herein and may be embodied in other forms. Like reference numerals denote like elements throughout the specification.

The present invention provides a multi-sensor 100. In an example, the multi-sensor 100 may be directly connected to a wire or conductor through which current flows. Alternatively, the multi-sensor 100 may be mounted inside an electronic device, a mechanical device, or a battery system. In an example, the multi-sensor 100 may be applied to a solid state relay (SSR) device. The SSR device, a device controlling electrical signals, controls current of an external load. The SSR device performs a relay function and controls current within an electronic circuit without mechanical contacts. However, devices to which the multi-sensor 100 is applied is not limited thereto.

In an example, the multi-sensor 100 according to the present invention may be applied to a busbar (not shown) that serves to connect a plurality of electrical circuits and distribute power in an electrical system or a device including the busbar. For example, the multi-sensor 100 may be coupled to a busbar provided in an external load input unit and output unit within the SSR device. In an example, the multi-sensor 100 may be provided as an integral unit with the busbar. However, this is merely an example, and the application examples are not limited thereto. Accordingly, the present invention may be applied to detect abnormalities in temperature and current in various devices.

In an example, the multi-sensor 100 may be a semiconductor integrated circuit (IC)-type current sensor.

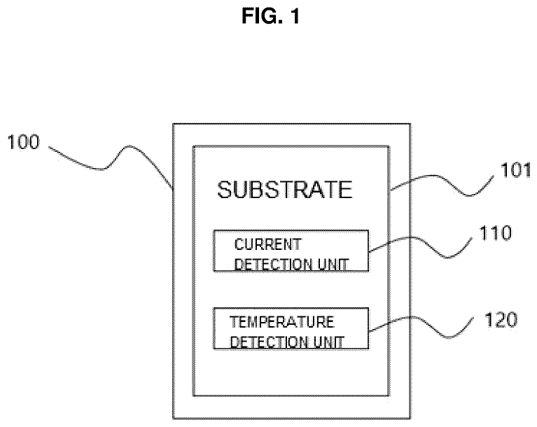

FIG. 1 is a block diagram illustrating a configuration of a multi-sensor according to an exemplary embodiment of the present invention.

Referring to FIG. 1, the multi-sensor 100 may include a substrate 101, a current detection unit 110, and a temperature detection unit 120.

The substrate 101 serves to support the components included in the multi-sensor 100 and to provide electrical connections. In an example, the current detection unit 110 and the temperature detection unit 120 are provided on the substrate 101. The semiconductor IC-type multi-sensor 100 may be provided as a single integrated sensor element by packaging the current detection unit 110 and the temperature detection unit 120 on the substrate 101. In an example, the current detection unit 110 and the temperature detection unit 120 are provided as thin film patterns formed on the substrate.

The current detection unit 110 detects and measures current flowing through an object to be measured. In an example, the current detection unit 110 is provided to detect and measure current flowing through the object to be measured in real time. In an example, the current detection unit 110 is directly connected to a wire or conductor through which current flows. Alternatively, the current detection unit 110 is coupled to a busbar. In an example, the current detection unit 110 is integrally coupled to the busbar to detect current flowing through the busbar.

In an example, the current detection unit 110 may be provided to measure a change in a magnetic field generated in a conductor through which current flows by utilizing a magnetoresistance effect. That is, the current detection unit 110 may detect a magnetic field generated when current flows and measure strength thereof, thereby detecting the flow of current.

In an example, the current detection unit 110 may include a planar hall resistor (PHR) IC element or a planar magnetic resistor (PMR) IC element to detect current.

The PHR IC device detects a magnetic field using a planar hall effect. The planar hall effect is a method of measuring a voltage difference that occurs as a path of current changes when a magnetic field is applied in a vertical direction to a conductor through which current flows. By utilizing the voltage difference, the magnitude and direction of the magnetic field may be accurately detected. It is a principle of determining a current state by measuring the voltage difference that occurs when the direction of current flow is perpendicular to a magnetic field.

The PMR IC device utilizes a planar magnetoresistance effect. The Magnetoresistance effect is a phenomenon in which resistance of a conductor changes when a magnetic field parallel to a conductor through which current flows is applied. By measuring the change in resistance, the magnitude and direction of the magnetic field may be determined. The PMR device detects current through changes in resistance caused by a magnetic field and have the advantage of being able to precisely measure the relationship between a magnetic field and current.

The existing current detection technology generally uses a current transformer (CT) to detect current. However, the CT method has many limitations in application due to the difficulty of miniaturization, high manufacturing costs, and the complexity of the process. In addition, while using a vertical hall sensor (VHS) method allows for manufacturing in the form of an IC, having the advantage of cost reduction, there are still limitations in terms of miniaturization and ease of processing because magnetic fields have to intersect in both the horizontal and vertical directions for current detection.

To solve these problems of existing technology, in the present invention, the current detection unit 110 is configured using a PHR or PMR IC device. The current detection unit 110 is designed to be sensitive to a magnetic field in the horizontal direction, thereby solving the problem of vertical intersection between the current detection device and a circuit that occurred in the existing technology. In addition, the PHR and PMR elements are sensitive to horizontal magnetic fields rather than vertical magnetic fields for current detection, thereby satisfying miniaturization, reduced manufacturing costs, and ease of processing.

The current detection unit 110 is provided as a PHR or PMR element, and by integrally coupling the multi-sensor 100 to a busbar, this technology may be extended to various devices and systems to which a busbar is applied. Furthermore, this method is insensitive to stray fields caused by the Earth's magnetic field, disturbances, temperature changes, etc., ensuring high reliability. Through this, current and temperature states may be detected very accurately, and a state may be monitored in real time and predictive maintenance may be performed inside the device including the busbar.

The temperature detection unit 120 detects and measures the temperature of an object to be measured. In an example, the object to be measured may be a wire or a conductor. Alternatively, the object to be measured may be a busbar. Alternatively, the object to be measured may be any one of a wire, a conductor, or a busbar and a connection portion thereof. For example, the temperature detection unit 120 may detect the temperature of the busbar. The multi-sensor 100 of the present invention is provided to detect temperature and current simultaneously, so that temperature measurement may be performed simultaneously with magnetic field measurement without the need to install a separate temperature sensor. Accordingly, a sensor may be miniaturized and manufacturing costs may be reduced, while providing the advantage of ease of processing.

In an example, the temperature detection unit 120 may include a resistant temperature detector (RTD). The RTD is provided so that a resistance value thereof changes according to temperature. In an example, the temperature detection unit 120 may be provided as a different type of detector that measures temperature using a material with resistance changing according to temperature. Alternatively, the temperature detection unit 120 may be provided to measure temperature using a material having voltage or current changing according to temperature.

In an example, the temperature detection unit 120 and the current detection unit 110 may be provided so that the two detection components operate independently of each other while simultaneously collecting data. In an example, the temperature detection unit 120 may be formed side by side with the current detection unit 110 on the substrate. Accordingly, there is an advantage of easy processing when forming the temperature detection unit 120 and the current detection unit 110 on the substrate.

Alternatively, the temperature detection unit 120 may be integrally coupled to one side of the current detection unit 110. Specifically, the temperature detection unit 120 may be integrally coupled to a lower or upper surface of the current detection unit 110. Accordingly, there is an advantage of being able to directly measure a temperature change of a load applied to the busbar. In addition, the inconvenience of manually implementing a separate IC or sensor for temperature measurement or implementing the same on a circuit may be eliminated, and as a result, there is an advantage of convenience, ease of processing, and price differentiation. In addition, by simultaneously detecting changes in current and temperature, abnormalities in a busbar contact portion, abnormalities in load current/voltage/power input, and abnormalities in the device including the busbar may be diagnosed.

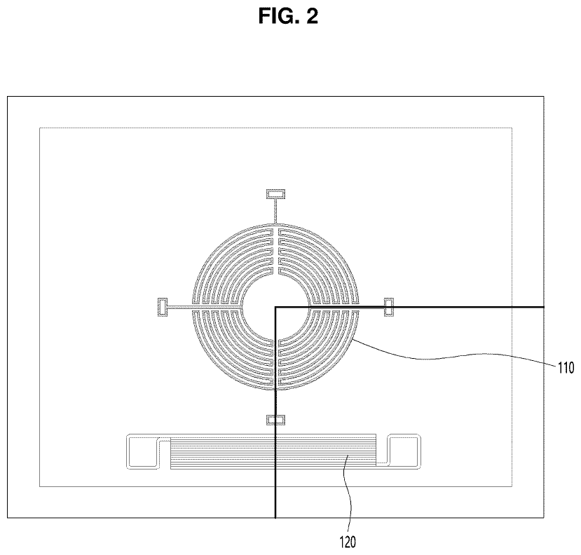

FIG. 2 is a schematic diagram illustrating the current detection unit 110 according to an exemplary embodiment of the present invention.

Referring to FIG. 2, the current detection unit 110 may be provided in a circular shape. In an example, the current detection unit 110 may be provided in a ring shape. In an example, the current detection unit 110 is a thin film pattern formed on the substrate. The thin film pattern forms the ring-shaped current detection unit 110. In an example, the thin-film pattern may be continuously connected as a single line without interruption. In an example, the thin film pattern includes interconnected arc portions 1110. The arc portions 1110 are provided in an arc shape, and a plurality of arc portions 1110 are combined to form a ring. In an example, the arc portion 1110 may be provided in an arc shape having a predetermined central angle with respect to the center of the ring. In an example, four arc portions 1110 may form a ring with a central angle of 90 degrees.

In an example, the arc portion 1110 includes a plurality of curved portions 1130 spaced apart by different distances from the center of the ring in a radial direction and straight portions 1140 connecting adjacent curved portions 1130. In an example, the straight portion 1140 is provided to connect any one of one side or the other side of an adjacent curved portion 1130. In an example, the straight portion 1140 is provided parallel to the radial direction of the ring.

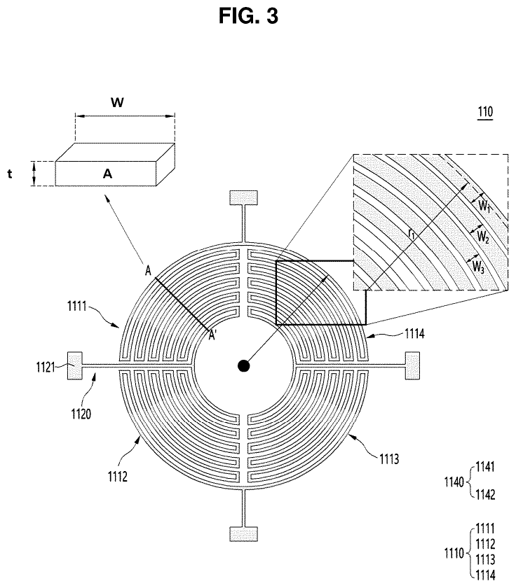

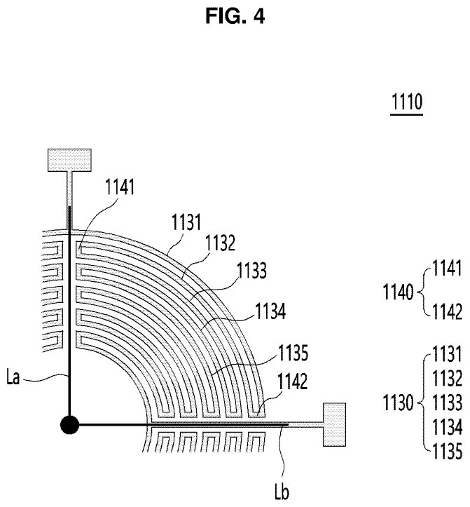

FIGS. 3 and 4 illustrate the arc portion 1110 of the present invention. In an example, the arc portion 1110 is provided with a first curved portion 1131, a second curved portion 1132, a third curved portion 1133, a fourth curved portion 1134, and a fifth curved portion 1135 in sequence. In an example, the first curved portion 1131 is located farthest radially from the center of the ring.

In an example, a straight portion 1141 located on one side of the arc portion 1110 and a straight portion 1142 located on the other side of the arc portion 1110 alternately connect adjacent curved portions 1130 with respect to the radial direction of the ring.

In an example, the first curved portion 1131 and the second curved portion 1132 are connected by the straight portion 1142 parallel to a virtual line Lb extending in the radial direction of the ring from one side of the second curved portion 1132. In addition, the second curved portion 1132 and the third curved portion 1133 are connected by the straight portion 1141 parallel to a virtual line La extending in the radial direction of the ring from the other side of the second curved portion 1132. In addition, the third curved portion 1133 and the fourth curved portion 1134 are connected by the straight portion 1142 parallel to the virtual line Lb extending in the radial direction of the ring from one side of the fourth curved portion 1134. The fourth curved portion 1134 and the fifth curved portion 1135 are connected by the straight portion 1141 parallel to the virtual line La extending in the radial direction of the ring from the other side of the fourth curved portion 1134.

In an example, the straight portion 1142 connecting the first curved portion 1131 and the second curved portion 1132 and the straight portion 1141 connecting the third curved portion 1133 and the fourth curved portion 1134 are located on the same line in the radial direction from the center of the ring, and the straight portion 1142 connecting the second curved portion 1132 and the third curved portion 1133 and the straight portion 1141 connecting the fourth curved portion 1134 and the fifth curved portion 1135 are located on the same line in the radial direction from the center of the ring. In an example, an arc portion 1110 in which the first curved portion 1131, the second curved portion 1132, the third curved portion 1133, the fourth curved portion 1134, and the fifth curved portion 1135 are arranged sequentially may be provided in a zigzag shape by the straight portion 1140.

In the example described above, five curved portions 1130 are provided as an exemplary embodiment of the arc portion 1110, but as illustrated in the drawings, the curved portions 1130 may be provided as five or more curved portions. The number of curved portions 1130 may be more or fewer than five as needed.

In an example, the arc portion 1110 includes a first arc portion 1111, a second arc portion 1112, a third arc portion 1113, and a fourth arc portion 1114. Each arc portion 1110 is arranged sequentially in a circumferential direction of the ring. Each arc portion 1110 is arranged evenly in the circumferential direction of the ring. In an example, adjacent arc portions 1110 are provided so that the curved portion 1130 located at the outermost edge of the ring or the curved portion 1130 located at the innermost edge of the ring are connected to each other. For example, the first arc portion 1111 and the second arc portion 1112 are connected through the curved portion 1130 located at the outermost edge of the ring. In addition, the third arc portion 1113 and the fourth arc portion 1114 are connected through the curved portion 1130 located at the outermost edge of the ring. In addition, the second arc portion 1112 and the third arc portion 1113 are connected through the curved portion 1130 located at the innermost edge of the ring. In addition, the first arc portion 1111 and the fourth arc portion 1114 are connected through the curved portion 1130 located at the innermost edge of the ring.

In an example, a connecting portion 1121 connecting an external circuit to a current detection unit is provided on the curved portion 1130 connecting adjacent arc portions 1110. A connection portion 1121 is formed with a contact portion 1121 for electrically connecting an external circuit to a current detection unit at one end thereof. In an example, the contact portion 1121 is provided to face outward in the radial direction of the ring at the midpoint of the curved portion 1130 connecting adjacent arc portions 1110. In an example, the contact portion 1121 may be located at the midpoint between adjacent arc portions 1110.

In an example, the current detection unit 110 may electrically extract a sensitivity characteristic signal of a sensor in the form of a Wheatstone Bridge. For example, the current detection unit 110 constitutes a Wheatstone bridge. In an example, each arc portion 1110 acts as a resistor of the Wheatstone bridge. For example, four arc portions 1110 may be provided, and the respective four arc portion 1110 may correspond to four resistors of the Wheatstone bridge, respectively. In an example, when a resistance value of the arc portion 1110 changes, a resistance imbalance occurs in the Wheatstone bridge circuit, and a current value is measured based thereon.

In an example, the curved portion 1130 is provided to have a distance r(i) in the radial direction from the center of the ring. Here, the distance r(i) is a distance from the center of the ring to the center of the curved portion 1130. The center of the curved portion 1130 is the midpoint in the direction of a ring width (wi) of the curved portion 1130.

For convenience, r(i) is referred to as the radius. A cross-section of each curved portion 1130 has the ring width (wi), a thin film thickness (t), and an area (A). Also, R is defined as resistance of the ring-shaped current detection unit, p is defined as resistivity of the current detection unit, I is defined as a length of a path through which current flows, and A is defined as a cross-sectional area (identical to the area of the curved portion 1130) through which current flows.

Here, the resistance of the ring satisfies the following formula.

$$R = ρ \frac{l}{A} = ρ \frac{2 π r ( i )}{t \cdot w ( i )}$$

In an example, the area (A) and thickness (t) of the thin film pattern constituting the current detection unit 110 are provided to be constant. Once the material of the thin film pattern is determined, the resistivity p of the current detection unit is also determined.

Accordingly, the factors determining the resistance R are the radius r(i) and the ring width w(i). Specifically, the resistance R is proportional to the radius r(i) and inversely proportional to the ring width w(i). In other words, the resistance R is proportional to

$$\frac{r ( i )}{w ( i )} .$$

In an exemplary embodiment,

$$\frac{r ( i )}{w ( i )}$$

is provided as a fixed constant value.

For example, when the first curved portion 1131 to the third curved portion 1133 have radii of r1, r2, and r3 and ring widths of w1, w2, and w3, respectively,

$$\frac{r ( 1 )}{w ( 1 )} , \frac{r ( 2 )}{w ( 2 )} , and \frac{r ( 3 )}{w ( 3 )}$$

are all provided to have the same value.

To this end, the ring width w(i) of the curved portion 1130 with a large radius r(i) is provided to be large. That is, the radius and the ring width are in a proportional relationship.

Fixing the r/w ratio improves the sensitivity and linearity of the current detection unit 110 and reduces hysteresis. This is because, when the r/w ratio is fixed, the electrical characteristics of the current detection unit 110 become predictable and exhibit a consistent response.

Accordingly, linearity, in which a proportional relationship between input and output is maintained constant, is improved. That is, a linear output is provided with respect to current changes, and non-linear distortion is reduced. In addition, hysteresis, in which an output signal retains a previous state upon changes in the input signal, is decreased. By fixing the r/w ratio, the sensor exhibits a constant and predictable response to current changes, thereby reducing repetitive changes in the output. That is, the reduction in hysteresis increases the stability of the output signal and ensures a more consistent response to current changes. Accordingly, due to the fixed r/w ratio, the current detection unit 110 exhibits predictable operation with a minimal change, enhancing accuracy by reducing fluctuations over time.

This may be verified experimentally.

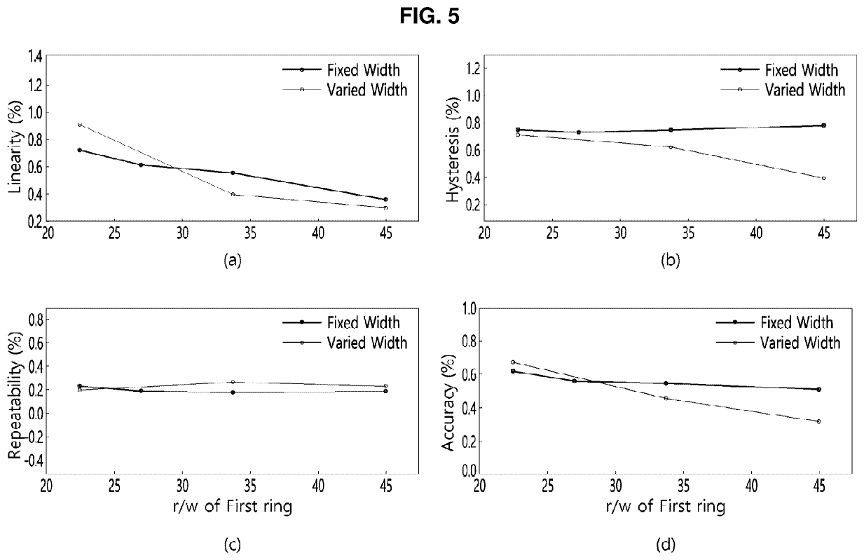

FIG. 5 shows graphs illustrating the performance of the current detection unit 110 according to an exemplary embodiment of the present invention.

In FIG. 5, to demonstrate the performance of the current detection unit 110 of the present invention, a fixed ring-width current detection unit, in which the ring width (w) is kept constant by maintaining the thickness of the thin film pattern constant when manufacturing the current detection unit 110, is compared with the current detection unit of the present invention in which the r/w ratio is fixed. Hereinafter, the current detection unit of the present invention having the fixed r/w ratio is referred to as a variable ring-width current detection unit.

In the case of the fixed ring-width current detection unit, since the ring width is fixed, the resistance value proportional to r/w is small in a region with a small radius and large in a region with a large radius, so the resistance is not evenly distributed when viewed over the entire current detection unit 110.

In contrast, in the variable ring-width current detection unit, since the r/w value is fixed, the resistance is evenly distributed when viewed across the entire current detection unit 110, regardless of the position of the curved portion 1130.

The values on the horizontal axis of FIG. 5 all represent the r/w of the curved portion 1130 located at the outermost edge of the arc portion 1110. In the case of the variable ring-width current detection unit, r/w is the same in all regions. Although not directly visible from the graph itself, as described above, in the case of the fixed ring-width current detection unit, the ring width is fixed, so the r/w value is large in a region far from the center of the ring and small in a region close to the center of the ring.

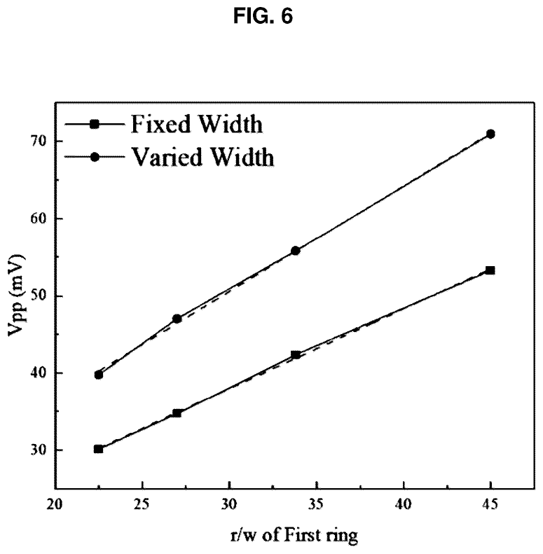

(a) of FIG. 5 is a graph illustrating linearity, FIG. 5(b) is a graph illustrating hysteresis, (c) of FIG. 5 is a graph illustrating reproducibility (consistency), (d) of FIG. 5 is a graph illustrating accuracy, and FIG. 6 is a graph illustrating the sensitivity of the sensor. The values shown in (a) of FIG. 5, (b) of FIG. 5, and (d) of FIG. 5 represent an error rate expressed as (measured value-reference value)/reference value %, and a smaller value indicates superior performance.

Referring to (a) of FIG. 5, as the r/w ratio increases, the error rate of linearity tends to decrease in both structures. This indicates that linearity increases as the r/w ratio becomes larger. In particular, it can be seen that the variable ring-width current detection unit maintains better linearity compared to the fixed ring-width current detection unit, starting from an r/w ratio of around 30 to 35.

Referring to (b) of FIG. 5, hysteresis shows a tendency for the error rate to decrease in both structures as the r/w ratio increases; however, across the entire region of r/w ratios, the variable ring-width current detection unit has a lower error rate than the fixed ring-width current detection unit. In addition, starting from an r/w ratio of around 30 to 35, the variable ring-width current detection unit shows a tendency for the error rate to decrease more rapidly than that of the fixed ring-width current detection unit. In other words, the variable ring-width current detection unit demonstrates better performance in hysteresis, which may be interpreted to mean that current detection with respect to resistance changes is more consistent.

Referring to (c) of FIG. 5, the reproducibility of the variable ring-width current detection unit and the fixed ring-width current detection unit is generally similar; however, it can be seen that the variable ring-width current detection unit is superior to the fixed ring width current detection unit, starting from an r/w ratio of around 25. Reproducibility is a value related to consistency in producing the same output for the same input, indicating that the variable ring width current detection unit produces the same output for the same input more frequently than the fixed ring-width current detection unit when the r/w ratio is around 30 to 40.

Referring to (d) of FIG. 5, accuracy indicates how closely a measured value matches an actual value. As the r/w ratio increases, the error rate of accuracy tends to decrease for both structures. In particular, it can be seen that the variable ring-width current detection unit maintains better accuracy than the fixed ring-width current detection unit, starting from an r/w ratio of around 25 to 30.

Referring to (a)-(d) of FIG. 5, it can be seen that the performance of the variable ring-width current detection unit is consistently excellent when the r/w ratio is 25 or higher. Accordingly, the r/w ratio of the current detection unit of the present invention may be provided as 25 or higher. In an example, the r/w ratio may be selected as 30.

Referring to FIG. 6, it can be seen that the sensitivity of the sensor in the variable ring width current detection unit is superior to the fixed ring-width detection unit across the entire region of the r/w ratio.

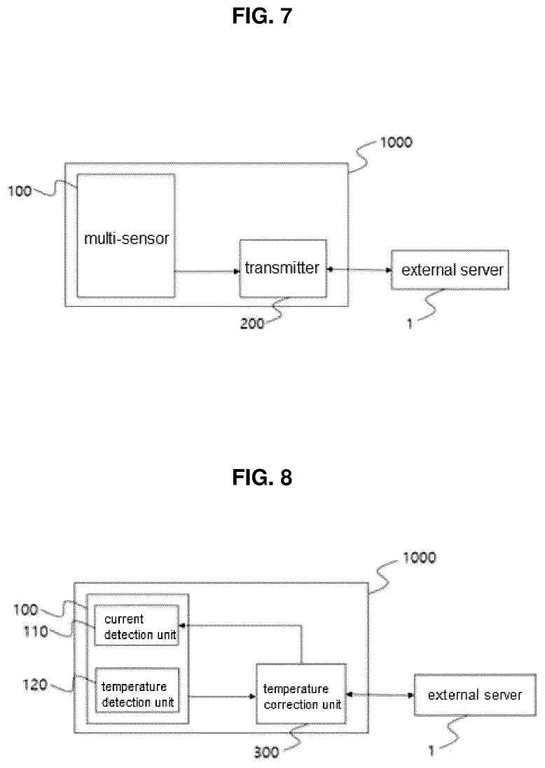

FIG. 7 is a block diagram illustrating a configuration of a system including a multi-sensor according to another exemplary embodiment of the present invention.

As shown in FIG. 7, a multi-sensor system 1000 according to another exemplary embodiment of the present invention may include the multi-sensor 100 including the features described above and a transmitter 200.

In the case of the related art, the related art includes a function to cut off power according to upper and lower limits of a threshold value.

Meanwhile, the transmitter 200 of the present invention may transmit current and temperature data obtained from the current detection unit 110 and the temperature detection unit 120 included in the multi-sensor 100 to the outside. Here, the outside may refer to an external server 1. Specifically, the transmitter 200 may transmit the current and temperature data to the external server 1 via a network, such as IO-link. Subsequently, a state of the busbar may be diagnosed based on the data obtained from the external server 1 and a preset algorithm, and predictive maintenance is possible.

FIG. 8 is a block diagram illustrating a configuration of the multi-sensor system 1000 according to another exemplary embodiment of the present invention.

As shown in FIG. 8, the multi-sensor system 1000 according to another exemplary embodiment of the present invention may further include a temperature correction unit 300.

The temperature correction unit 300 may perform a temperature correction function of the PHR sensor based on temperature data obtained from the temperature detection unit 120 included in the multi-sensor 100. The PHR sensor requires correction based on temperature, and a measurement correction algorithm reflecting real-time data may be implemented. Accordingly, there is an advantage in that the sensing accuracy may be improved by two times or more.

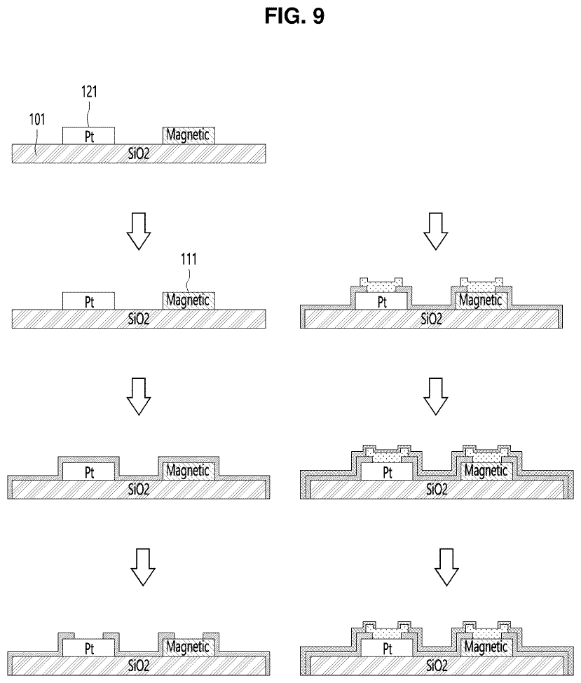

FIG. 9 is a schematic diagram illustrating a method of manufacturing the multi-sensor 100 according to an exemplary embodiment of the present invention.

As illustrated in FIG. 9, the method of manufacturing a multi-sensor includes forming an insulating film on one surface of the substrate 101 in operation S100, forming a first thin film pattern 121 for temperature measurement in an upper portion of the insulating film in operation S200, forming a second thin film pattern 111 for magnetic field measurement in an upper portion of the insulating film in operation S300, forming an insulating film again in operation S400, forming a contact hole in any one of the first thin film pattern 121 and the second thin film pattern 111 in operation S500, and packaging the multi-sensor in operation S600.

Here, the first thin film pattern 121 forms the temperature detection unit 120, and the second thin film pattern 111 forms the current detection unit 110.

First, in operation S100, the substrate 101 is preferably the substrate 101 including Si, and an insulating film may be formed on one surface of the Si substrate 101. Here, considering high insulation characteristics, low dielectric loss, and thermal stability, the insulating film preferably includes at least one of SiO₂, Si₃N₄, Al₂O₃, C, GaN, TiO₂, and Ta₂O, but is not limited thereto.

Subsequently, in operation S200, the first thin film pattern 121 may be formed to form a temperature sensor including a positive temperature coefficient (PTC) characteristic. Here, the first thin film pattern 121 may include Pt metal. Here, when a metal is applied to the first thin film pattern 121, it may have a minor influence on the intensity of current to be measured due to an eddy current effect. However, since the influence is very small compared to the intensity of a magnetic field to be measured, the influence may be disregarded. In addition, the eddy current problem may be minimized through a sensor calibration process.

In operation S300, the second thin film pattern 111 may be formed, and the patterning thereof may be differently applied and configured depending on the sensitivity and operating range of the sensor. In addition, the second thin film pattern 111 may include at least one of IrMn and NiFe. Here, to further improve the sensing sensitivity, it is preferable to include at least one of IrMn, NiFe, and Cu, but is not limited thereto. In an example, the second thin film pattern 111 may be designed to provide a fixed r/w ratio as described above. In an example, the r/w ratio is provided as 25 or higher.

In the example described above, the first thin film pattern 121 and the second thin film pattern 111 are described as being formed to be spaced apart from each other on the substrate. However, alternatively, the first thin-film pattern 121 and the second thin-film pattern 111 may be disposed in an overlapping upper and lower relationship, rather than in different regions on the substrate 101, to minimize the fabrication area of the sensor. Specifically, the first thin film pattern 121 may be disposed to be formed above or below the second thin film pattern 111. For example, if the first thin film pattern 121 is configured below the substrate 101, it is also possible to configure a temperature sensor utilizing a change in forward voltage drop according to temperature of an Si P/N diode. In this case, it is appropriate to configure the first thin film pattern 121 below the second thin film pattern 111.

In operation S400, the insulating film may be formed again. Here, considering high insulation properties, low dielectric loss, and thermal stability, it is preferable for the insulating film to include at least one of SiO₂, Si₃N₄, Al₂O₃, C, GaN, TiO₂, and Ta₂O, but is not limited thereto.

In operation S500, a contact hole may be formed in any one of the first thin film pattern 121 and the second thin film pattern 111 using a reactive-ion etching (RIE) process.

Finally, in operation S600, the multi-sensor may be packaged. Specifically, an electrode may be formed in operation S600-1, an insulating film may be formed to provide electrical insulation between the electrode and other active regions and patterning is performed in operation S600-2, and a pad region may be opened for electrical connection with an external circuit in operation S600-3. Here, the electrode may include a conductive electrode, for example, Ti/Al.

According to an exemplary embodiment of the present invention as described above, by fixing the r/w value, the multi-having with good linearity, reproducibility, accuracy, and sensitivity may be provided.

In addition, according to an exemplary embodiment of the present invention, by fixing the r/w value, the multi-sensor capable of reducing hysteresis may be provided.

The effects of the present invention are not limited to the effects described above, and unmentioned effects will be clearly understood by those skilled in the art to which the present invention pertains.

Although the preferred exemplary embodiments of the present invention have been described above, the exemplary embodiments disclosed in the present invention are not intended to limit the technical spirit of the present invention, but are only for explanation. Therefore, the technical spirit of the present invention includes not only each disclosed exemplary embodiment, but also a combination of the disclosed exemplary embodiments, and furthermore, the scope of the technical spirit of the present invention is not limited by these exemplary embodiments. In addition, those skilled in the art to which the present invention pertains may make many changes and modifications to the present invention without departing from the spirit and scope of the appended claims, and all such appropriate changes and modifications, as equivalents, are to be regarded as falling within the scope of the present invention.

What is claimed is:

1. A multi-sensor including a current detection unit detecting current flowing through an object to be measured,
wherein the current detection unit includes:
a plurality of arc-shaped arc portions combined to form a ring,
wherein the arc portion includes:
a plurality of curved portions disposed at different radii r(i) in a radial direction from a center of the ring and having a predetermined ring width w(i); and
a straight portion connecting the curved portions adjacent to each other,
wherein at least one of the plurality of curved portions connects adjacent arc portions, and
wherein the curved portion is provided such that the ring width is proportional to the radius.

2. The multi-sensor of claim 1, wherein r(i)/w(i) is provided as a fixed constant value.

3. The multi-sensor of claim 1, wherein resistance of the current detection unit is configured to be calculated using the following formula:
$$R = ρ \frac{l}{A} = ρ \frac{2 π r ( i )}{t \cdot w ( i )}$$
(t: thickness of a cross-section of the curved portion, A: area of the cross-section of the curved portion, p: resistivity of the current detection unit, l: length of a path through which current flows in the current detection unit).

4. The multi-sensor of claim 1, wherein a first arc portion, a second arc portion, a third arc portion, and a fourth arc portion of the arc portion are sequentially and evenly disposed in a circumferential direction of the ring.

5. The multi-sensor of claim 4, wherein:
the first arc portion and the second arc portion are connected by the curved portion located at an outermost edge,
the second arc portion and the third arc portion are connected by the curved portion located at an innermost edge,
the third arc portion and the fourth arc portion are connected by the curved portion located at the outermost edge, and
the fourth arc portion and the first arc portion are connected by the curved portion located at the innermost edge.

6. The multi-sensor of claim 1, wherein a straight portion located on one side of the arc portion and a straight portion located on the other side of the arc portion with respect to a radial direction of the ring alternately connect adjacent curved portions.

7. The multi-sensor of claim 6, wherein:
the curved portion includes a first curved portion, a second curved portion, a third curved portion, a fourth curved portion, and a fifth curved portion that are sequentially provided,
the first curved portion and the second curved portion are connected by the straight portion on one side of the arc portion,
the second curved portion and the third curved portion are connected by the straight portion on the other side of the arc portion,
the third curved portion and the fourth curved portion are connected by the straight portion on the one side, and
the fourth curved portion and the fifth curved portion are connected by the straight portion on the other side.

8. The multi-sensor of claim 7, wherein the curved portion is disposed in a zigzag pattern.

9. The multi-sensor of claim 1, further comprising:
a connecting portion connecting the current detection unit to an external circuit,
wherein the connecting portion extends outward in the radial direction of the ring from the curved portion connecting the adjacent arc portions, and
wherein a contact portion for electrically connecting the external circuit to the current detection unit is provided at one end.

10. The multi-sensor of claim 1, wherein the current detection unit constitutes a Wheatstone bridge.

11. The multi-sensor of claim 1, wherein the current detection unit is provided as a planar hall resistor (PHR) IC element or a planar magnetic resistor (PMR) IC element.

12. The multi-sensor of claim 1, further comprising:
a substrate including the current detection unit formed on one surface; and
a temperature detection unit formed on the substrate to detect temperature of the object to be measured.

13. A multi-sensor including a current detection unit detecting current flowing through an object to be measured, wherein:
the current detection unit includes a single continuous thin film pattern forming a ring shape,
the thin film pattern includes a plurality of arc-shaped arc portions disposed in a circumferential direction,
each arc portion includes a plurality of curved portions and a straight portion connecting the curved portions, and
the plurality of arc portions are continuously connected to each other through the curved portions to form a single, uninterrupted current path throughout the entire ring.

14. The multi-sensor of claim 13, wherein the arc portion includes:
a plurality of curved portions disposed at different radii r(i) in a radial direction from a center of the ring and having a predetermined ring width w(i); and
a straight portion connecting the curved portions adjacent to each other,
wherein at least one of the plurality of curved portions connects adjacent arc portions, and
wherein the curved portion is provided such that the ring width is proportional to the radius.

15. The multi-sensor of claim 13, wherein r(i)/w(i) is provided as a fixed constant value.

16. The multi-sensor of claim 13, wherein resistance of the thin film pattern is calculated using the following formula:
$$R = ρ \frac{l}{A} = ρ \frac{2 π r ( i )}{t \cdot w ( i )}$$
(t: thickness of a cross-section of the curved portion, A: area of the cross-section of the curved portion, p: resistivity of the current detection unit, l: length of a path through which current flows in the current detection unit).

17. The multi-sensor of claim 13, wherein the thin film pattern constitutes a Wheatstone bridge.
